(19) United States
(12) Patent Application Publication
(10) Pub. No.: US 2012/0275243 A1
(43) Pub. Date: Nov. 1, 2012

(54) SEMICONDUCTOR MEMORY DEVICE

(75) Inventors: Dong Hwee Kim, Suwon-si (KR); Tae Sik Yun, Seoul (KR)

(73) Assignee: HYNIX SEMICONDUCTOR INC., Icheon-si (KR)

(21) Appl. No.: 13/244,363

(22) Filed: Sep. 24, 2011

(30) Foreign Application Priority Data
Apr. 26, 2011 (KR) 10-2011-0039213

(51) Int. Cl. G11C 7/00; G11C 7/10

(52) U.S. Cl. 365/189.11; 365/191; 365/194

(57) ABSTRACT

A semiconductor memory device includes: a first switch configured to couple a bit line to a first input/output line in response to an output selection signal including a pulse which is generated in response to a read command or write command; and a second switch configured to couple the first input/output line to a second input/output line in response to a switching control signal which is enabled after the output selection signal is enabled.

### CROSS-REFERENCES TO RELATED APPLICATIONS

The present application claims priority under 35 U.S.C 119(a) to Korean Application No. 10-2011-0039213, filed on Apr. 26, 2011, in the Korean intellectual property Office, which is incorporated herein by reference in its entirety.

### BACKGROUND

Data in a semiconductor memory device is passed through a pad in a read or write operation for inputting and outputting of data to and from a memory cell. In order to perform a read or write operation, an active operation should precede.

An active operation is performed by: decoding a row address and selecting a word line, loading the data of a memory cell coupled to the selected word line on a bit line by charge sharing, and sensing the data loaded on the bit line and then amplifying the sensed data by a bit line sense amplifier. The amplified data sensed from the bit line by an active operation is then considered to be in a prepared state for performing a read or write operation.

To perform a read or write operation in a prepared state, the bit line is coupled to the input/output lines by a column selection signal YI generated by a column path operation, and afterwards a data input/output operation may be performed.

With reference to FIG. 1, a read operation and a write operation which are performed in a conventional semiconductor memory device will be described in more detail.

First, a word line WL is selected and activated in synchronization with an active command ACT, and an input/output line switching signal IOSW is also enabled to a logic high level. Data in a memory cell coupled to the activated word line WL is loaded onto a bit line, and then the loaded data is sensed and amplified by a bit line sense amplifier. Furthermore, a first input/output line pair SIO/SIOB (not shown) and a second input/output line pair LIO/LIOB are coupled by the enabled input/output line switching signal IOSW.

Next, when a read command RD is inputted to perform a read operation, a pulse of an output selection signal YI is generated to transmit data between a bit line pair BL/BLB and the first input/output line pair SIO/SIOB. The first input/output line pair SIO/SIOB has been coupled to the second input/output line pair LIO/LIOB by a preceded active operation, and the first input/output line pair SIO/SIOB (not shown) and the second input/output line pair LIO/LIOB have been precharged. This lowers the voltage difference VD1 between the bit line pair BL/BLB due to the line loading of the first and second input/output line pairs LIO/LIOB, SIO/SIOB. This may lead to data flopping, in which the signal levels of the data loaded on the bit line pair BL/BLB are flopped shown as VD1 in FIG. 1.

Then, when a write command WT is inputted to perform a write operation, a pulse of the output selection signal YI is generated to couple the bit line pair BL/BLB to the first input/output line pair SIO/SIOB. Since data to be stored in a memory cell are transmitted to the bit line pair BL/BLB through the second input/output line pair LIO/LIOB and the first input/output line pair SIO/SIOB, the drivability of a data driver should be set to a large value. When the drivability of the data driver is not set to a sufficiently large value, a level transition time VTD1 of the bit line pair BL/BLB may be increased to cause a reduction in operation speed, in case in which data having an opposite level to that of the data loaded on the bit line pair BL/BLB are inputted.

### SUMMARY

An embodiment of the present invention relates to a semiconductor memory device capable of substantially preventing data flopping from occurring during a read operation and increasing operation speed during a write operation.

In an embodiment, a semiconductor memory device includes: a first switch configured to couple a bit line to a first input/output line in response to an output selection signal including a pulse which is generated in response to a read command or write command; and a second switch configured to couple the first input/output line to a second input/output line in response to a switching control signal which is enabled after the output selection signal is enabled.

In an embodiment, a semiconductor memory device includes: a first input/output line coupled to a bit line in response to an output selection signal which is enabled during an active operation; and a switch configured to couple the first input/output line to a second input/output line in response to a switching control signal which is driven to a larger level than in a read operation, during a write operation.

In an embodiment, a semiconductor memory device includes: a supply voltage driving unit configured to drive a supply voltage to a power supply voltage, after a preset period passes since an input of a read command, and drive the supply voltage to a high voltage having a higher level than the power supply voltage, when a write command is inputted; a control signal driving unit configured to drive a switching control signal to the supply voltage applied from the supply voltage driving unit in response to an input/output switching signal; and a first switch unit configured to couple first and second input/output lines in response to the switching control signal.

### BRIEF DESCRIPTION OF THE DRAWINGS

The above and other aspects, features and other advantages will be more clearly understood from the following detailed description taken in conjunction with the accompanying drawings, in which:

FIG. 1 is a timing diagram explaining read and write operations which are performed in a conventional semiconductor memory device;

FIG. 2 is a block diagram illustrating the configuration of a semiconductor memory device in accordance with an embodiment of the present invention;

FIG. 3 is a circuit diagram of a switching control signal generator included in the semiconductor memory device of FIG. 2; and

FIG. 4 is a timing diagram explaining read and write operations which are performed in the semiconductor memory device in accordance with the embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

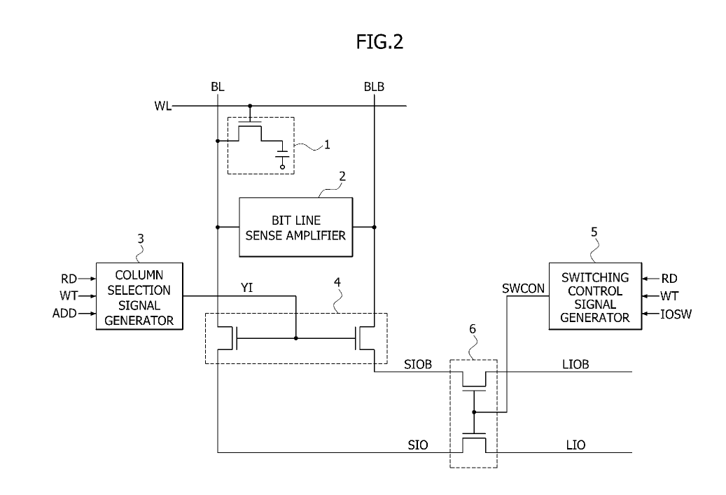

FIG. 2 is a block diagram illustrating the configuration of a semiconductor memory device in accordance with an embodiment of the present invention.

Referring to FIG. 2, the semiconductor memory device in accordance with an embodiment of the present invention includes a memory cell 1, a bit line sense amplifier 2, a column selection signal generator 3, a first switch 4, a switching control signal generator 5, and a second switch 6.

The memory cell 1 is configured to load data on a bit line BL through charge sharing when a word line WL is activated. The bit line sense amplifier 2 is configured to sense and amplify the data loaded on a bit line pair BL/BLB.

The column selection signal generator 3 is configured to generate an output selection signal YI by decoding an address ADD, when a read command RD or write command WT is inputted. The output selection signal YI includes pulses which are generated in synchronization with the read command RD and the write command WT.

The first switch 4 is configured to couple the bit line pair BL/BLB to a first input/output SIO/SIOB when a pulse of the output selection signal YI is inputted.

The switching control signal generator 5 is configured to generate a switching control signal SWCON from an input/output switching signal IOSW in response to the read command RD and the write command WT. The switching control signal SWCON is driven to a power supply voltage VDD after a preset period passes since the input of the read command RD, and driven to a high voltage VPP When the write command WT is inputted. Here, the high voltage VPP has a higher level than the power supply voltage VDD.

The second switch 6 is configured to couple the first input/output line pair SIO/SIOB to the second input/output line pair LIO/LIOB, when the switching control signal SWCON is enabled.

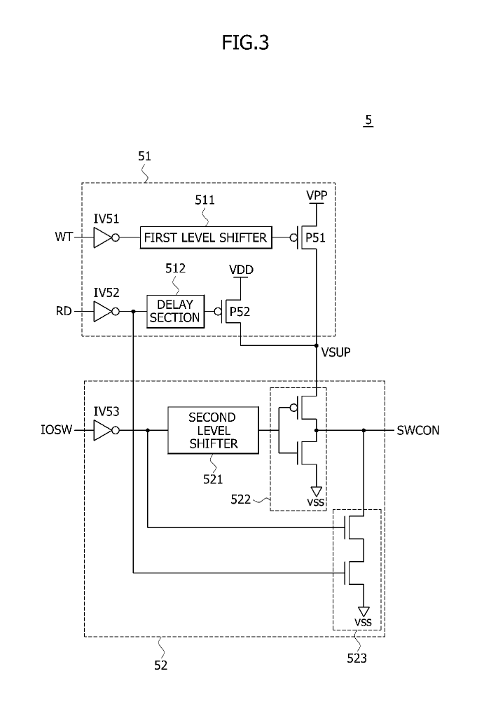

Referring to FIG. 3, the configuration of the switching control signal generator 5 will be described in more detail as follows.

As illustrated in FIG. 3, the switching control signal generator 5 includes a supply voltage driving unit 51 and a control signal driving unit 52. The supply voltage diving unit 51 is configured to drive a supply voltage VSUP to either a power supply voltage VDD or a high voltage VPP. The supply voltage VSUP would be driven to a power supply voltage VDD after a preset time delay when a read command RD is inputted, or the supply voltage VSUP would be driven to a high voltage VPP when a write command WT is inputted. The control signal driving unit 52 is configured to drive the switching control signal SWCON to the supply voltage VSUP in response to the input/output switching control signal IOSW.

The supply voltage driving unit 51 includes, inter alia, an inverter IV51, a first level shifter 511, a PMOS transistor P51, an inverter IV52, a delay section 512, and a PMOS transistor P52. The inverter IV51 is configured to buffer the write command WT. The first level shifter 511 is configured to level-shift an output signal of the inverter IV51. The PMOS transistor P51 is configured to operate as a driving element which drives the supply voltage VSUP to the high voltage VPP in response to an output signal of the level shifter 511. The inverter IV52 is configured to buffer the read command RD. The delay section 512 is configured to delay an output signal of the inverter IV51 by a preset period of time. The PMOS transistor P52 is configured to operate as a driving element which drives the supply voltage VSUP to the power supply voltage VDD in response to an output signal of the delay section 512. The first level shifter 511 level-shifts a signal which swings between a ground voltage VSS and the power supply voltage VDD, and outputs the level-shifted signal as a signal which swings between the ground voltage VSS and the high voltage VPP.

The control signal driving unit 52 includes an inverter IV53, a second level shifter 521, a buffer section 522, and a precharging section 523. The inverter IV53 is configured to buffer the input/output switching signal IOSW. The second level shifter 521 is configured to level-shift an output signal of the inverter IV53. The buffer section 522 is configured to receive the supply voltage VSUP, buffer an output signal of the second level shifter 521, and output the buffered signal as the switching control signal SWCON. The precharging section 523 is configured to precharge the switching control signal SWCON with the ground voltage VSS in response to the input/output switching signal IOSW and the read command RD, during a precharging operation. The input/output switching control signal IOSW is enabled to a logic high level in synchronization with an active command ACT, and disabled to a logic low level in synchronization with a precharge command PCG.

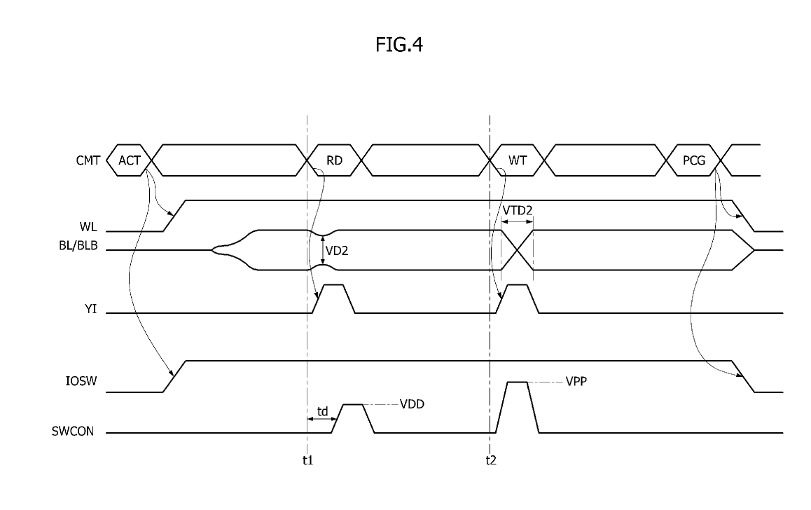

The read and write operations of the semiconductor memory device configured in such a manner will be described with reference to FIG. 4.

In response to an active command ACT, a word line WL is selected and activated and an input/output line switching signal IOSW is enabled. The data in the memory cell 1 coupled to the activated word line WL is loaded onto the bit line BL and then sensed and amplified by the bit line sense amplifier 2.

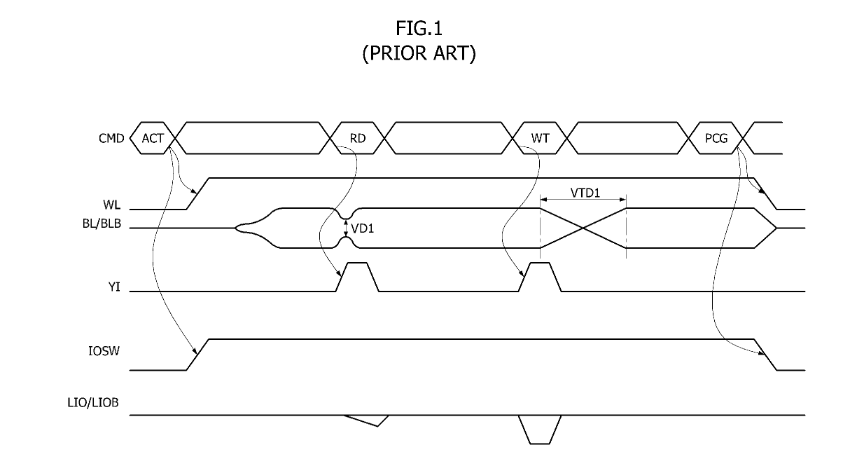

Next, when a read command RD is inputted at t1 in FIG. 4 to perform a read operation, an output selection signal YI is generated as a pulse to turn on the first switch 4 such that the bit line pair BL/BLB and the first input/output line pair SIO/SIOB are coupled to each other. The switching control signal generator 5 generates a switching control signal SWCON (which is driven to the power supply voltage VDD when the read command is inputted after a preset time delay from the delay section 512) and turns on the second switch 6. The switching control signal SWCON is driven to the power supply voltage VDD after the first switch 4 is turned on and then turns on the second switch 6. Therefore, a voltage difference VD2 between the bit line pair BL/BLB is reduced only by line loading of the first input/output line pair SIO/SIOB. The voltage difference VD2 between the bit line pair BL/BLB is therefore secured in a more stable manner (e.g., VD2 in FIG. 4) than in the case of a conventional semiconductor memory device such as that (e.g., VD1) shown in FIG. 1. Accordingly, it is possible to substantially prevent data flopping which occurs when the levels of data loaded on the bit line pair BL/BLB are turned over.

Next, when a write command WT is inputted at t2 shown in FIG. 5 to perform a write operation, the output selection signal YI is generated as a pulse to couple the bit line pair BL/BLB to the first input/output line pair SIO/SIOB. The switching control signal generator 5 generates a switching control signal SWCON (which is driven to a high voltage VPP when the write command WT is inputted) and turns on the second switch 6. Since the switching control signal SWCON is driven to the high voltage VPP having a higher level than in the read operation, the turn-on resistance of the second switch 6 coupling the first input/output line pair SIO/SIOB to the input/output line pair LIO/LIOB is reduced. Therefore, when data having an opposite level to that of the data loaded on the bit line pair BL/BLB are inputted during the write operation, the level transition time VTD2 of the bit line pair BL/BLB is reduced in comparison with the conventional semiconductor memory device.

As described above, the semiconductor memory device in accordance with an embodiment of the present invention enables the switching control signal SWCON after the pulse of the output selection signal YI is generated, and thus stably secures the voltage difference VD2 between the bit line pair BL/BLB, during a read operation. During a write operation, the semiconductor memory device drives the switching control signal SWCON to the high voltage VPP to reduce the turn-on resistance of the second switch 6. Accordingly, the operation speed is much improved.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor memory device comprising a memory cell connected to a bit line, the semiconductor memory device comprising:
a first switch configured to couple the bit line to a first input/output line in response to an output selection signal including a pulse which is generated in response to a read command or write command; and
a second switch configured to couple the first input/output line to a second input/output line in response to a switching control signal which is enabled after the output selection signal is enabled;

2. The semiconductor memory device of claim 1, further comprising a switching control signal generator configured to output the switching control signal, wherein the switching control signal generator is capable of adjusting the voltage level and the output timing of the switching control signal in response to the read command or the write command.

3. The semiconductor memory device of claim 1, further comprising:
a column selection signal generator configured to output an output selection signal in synchronization with the read command or the write command, wherein the output selection signal is a pulse signal to enable the first switch to couple the bit line to the first input/output line.

4. The semiconductor memory device of claim 1, wherein, when the read command is inputted, the switching control signal having a first voltage level is outputted.

5. The semiconductor memory device of claim 3, wherein, when the write command is inputted, the switching control signal having a second voltage level, which is higher than the first voltage level, is outputted.

6. The semiconductor memory device of claim 5, wherein the input/output switching signal is enabled in response to an active command, and disabled in response to a precharge command.

7. The semiconductor memory device of claim 5, wherein the first voltage is an external voltage and the second voltage is higher than the external voltage.

8. The semiconductor memory device of claim 2, wherein the switching control signal generator comprises:
a supply voltage driving unit configured to receive the first and second voltages and output the first voltage as a supply voltage in response to the read command and output the second voltages as the supply voltage in response to the write command.

9. The semiconductor memory device of claim 8, wherein the supply voltage driving unit comprises:
a delay section configured to delay for a predetermined period of time the outputting of the first voltage as the supply voltage in response to the read command; and
a driving element configured to drive the supply voltage to a power supply voltage in response to an output signal of the delay unit.

10. The semiconductor memory device of claim 9, wherein the switching control signal generator further comprises:
a control signal driving unit configured to output the supply voltage as the switching control signal in response to the input/output switching signal.

11. The semiconductor memory device of claim 10, wherein the switching control signal is precharged to a ground voltage in response to the read command and the input/output switching signal prior to outputting the first voltage as the switching control signal.

12. A semiconductor memory device comprising:
a first input/output line configured to be coupled to a bit line in response to an output selection signal which is enabled during an active operation; and
a switch configured to couple the first input/output line to a second input/output line in response to a switching control signal which is driven to a larger level in a read operation than in a write operation.

13. The semiconductor memory device of claim 12, further comprising:
a first level shifter configured to level-shift a signal obtained by buffering the write command;
a driving element configured to drive a supply voltage to a high voltage having a higher level than a power supply voltage in response to an output signal of the first level shifter;
a second level shifter configured to level-shift a signal obtained by buffering an input/output switching signal; and
a buffer configured to receive the supply voltage, buffer an output signal of the second level shifter, and output the buffered signal as the switching control signal.

14. The semiconductor memory device of claim 13, wherein the input/output switching signal is enabled in response to an active command, and disabled in response to a precharge command.

15. A semiconductor memory device comprises:
a supply voltage driving unit configured to drive a supply voltage to a power supply voltage in response to a read command, and to drive the supply voltage to a high voltage having a higher level than the power supply voltage in response to a write command;
a control signal driving unit configured to drive a switching control signal to the supply voltage applied from the supply voltage driving unit in response to an input/output switching signal; and
a first switch unit configured to couple first and second input/output lines in response to the switching control signal.

16. The semiconductor memory device of claim 15, wherein the supply voltage driving unit comprises:
a level shifter configured to level-shift a signal obtained by buffering the write command;
a first driving element configured to drive a supply voltage to the high voltage in response to an output signal of the first level shifter;
a delay section configured to delay a signal obtained by buffering the read command by the preset period; and
a second driving element configured to drive the supply voltage to the power supply voltage in response to an output signal of the delay section.

17. The semiconductor memory device of claim 15, wherein the input/output switching signal is enabled in response to an active command, and disabled in response to a precharge command.

18. The semiconductor memory device of claim 17, wherein the control signal driving unit comprises:
a level shifter configured to level-shift a signal obtained by buffering the input/output switching control signal; and
a buffer section configured to receive the supply voltage, buffer an output signal of the level shifter, and output the buffered signal as the switching control signal.

19. The semiconductor memory device of claim 15, further comprising a second switch unit configured to couple a bit line to the first input/output line in response to an output selection signal including a pulse which is generated in response to the read command or write command.
